(19) United States
(12) Patent Application Publication
(10) Pub. No.: US 2025/0093821 A1
(43) Pub. Date: Mar. 20, 2025

(54) REINFORCED WATCH CASE

(71) Applicant: ROLEX SA, Geneva (CH)

(72) Inventor: Alain Sémoroz, Lausanne (CH)

(73) Assignee: ROLEX SA, Geneva (CH)

(21) Appl. No.: 18/727,654

(22) PCT Filed: Jan. 10, 2023
(86) PCT No.: PCT/EP2023/050451

§ 371 Date: Jul. 9, 2024

(30) Foreign Application Priority Data
Jan. 13, 2022 (EP) 22151427.6

(51) Int. Cl. G04B 39/02; C30B 29/20; G04B 37/00; G04B 37/22; G04B 39/00

(52) U.S. Cl. CPC G04B 39/02; C30B 29/20; G04B 37/0008; G04B 37/22; G04B 39/006

(57) ABSTRACT

The wristwatch includes a case middle (3) and a load-reacting surface (2a) which is a surface of a load-reacting ring (2) distinct from the case middle (3), and a protective casing including the crystal (1), the case middle (3), and the load-reacting ring (2) housed within the case middle (3) including the load-reacting surface (2a) against which the crystal (1) bears, and a back (4) bearing against the load-reacting ring (2).

The invention relates to a wristwatch case. The invention also relates to a wristwatch comprising such a case.

Application EP1916576 discloses a device for fixing a watch crystal, which device is integrated into a watertight watch capable of withstanding very great depths, typically of between 3000 and 5000 meters, which have the specific feature of comprising within it a lateral wall designed to withstand the pressure loadings encountered at such depths.

Other solutions for obtaining watertightness in a watch case allowing such watches to reach great depths are known, such as, for example, the one described in document EP3896535.

The existing solutions provide the ability to withstand the high stress loadings encountered at such depths. However, they have the disadvantage of requiring a significant thickness of watch case, which has reached the maximum possible limit for wristwatch applications. This maximum thickness therefore, for example, prevents wristwatches from being developed for greater depths.

The object of the invention is to provide a wristwatch case suitable for use at very great depths and having a reduced thickness compatible with integration into a wristwatch.

To this end, the invention relies upon a wristwatch case wherein this case comprises a sapphire crystal of which the optical axis is perpendicular or substantially perpendicular to the plane of the crystal, particularly a crystal having a “type C” crystallographic orientation, particularly a sapphire obtained by the Kyropoulos technique or by an EFG method of crystal growth.

In addition, an interior surface of the crystal bears against a load-reacting surface of the watch case. The area of the load-reacting surface, which is to say the area over which part of the interior surface of the crystal bears against said load-reacting surface, is referred to as A2a, and the total area of the interior surface of the crystal, comprising the aforementioned bearing part and the non-bearing part, is referred to as A1a. According to the invention, the ratio A2a/A1a is greater than or equal to 0.2, or is even greater than or equal to 0.3, or is even greater than or equal to 0.35, or is even greater than or equal to 0.4.

The invention is defined specifically by the claims.

These subjects, features and advantages of the present invention will be set out in detail in the following nonlimiting description of a particular embodiment in relation to the appended figures, in which:

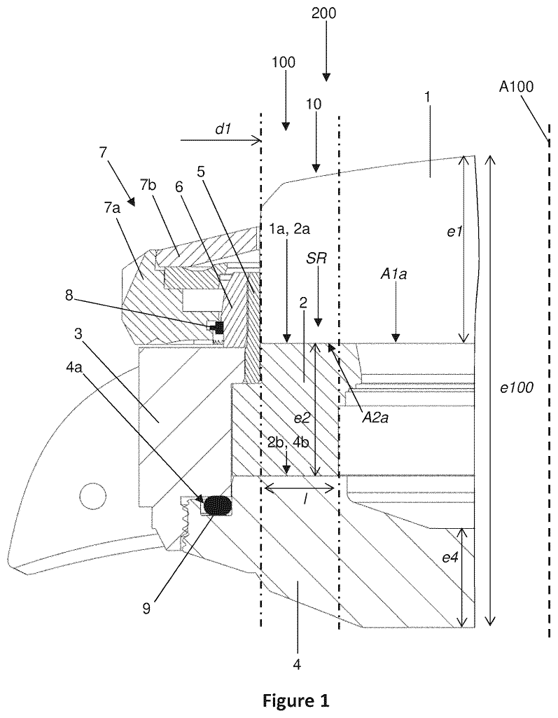

FIG. 1 is a view in cross section passing through a plane perpendicular to the watch case and containing the axis of the watch case, of a wristwatch case according to one embodiment of the invention.

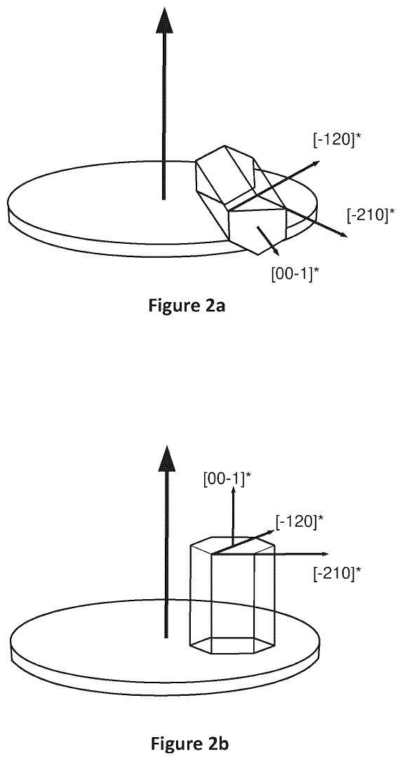

FIGS. 2a and 2b illustrate sapphire crystals respectively of types A and C, in which the orientation has been schematically indicated.

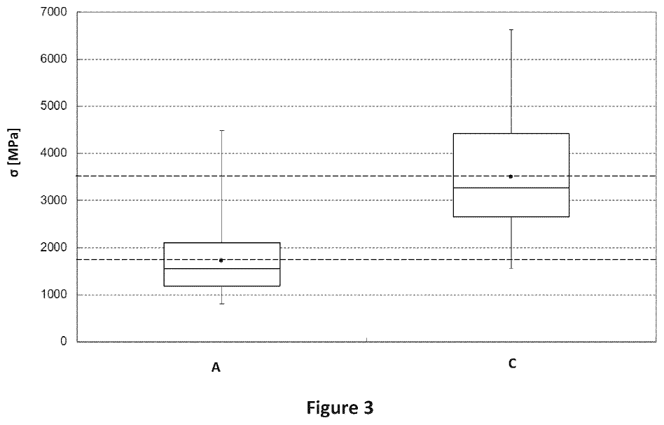

FIG. 3 is a graph providing a comparison between the mean breaking stresses of two batches of sapphire crystals of types A and C respectively.

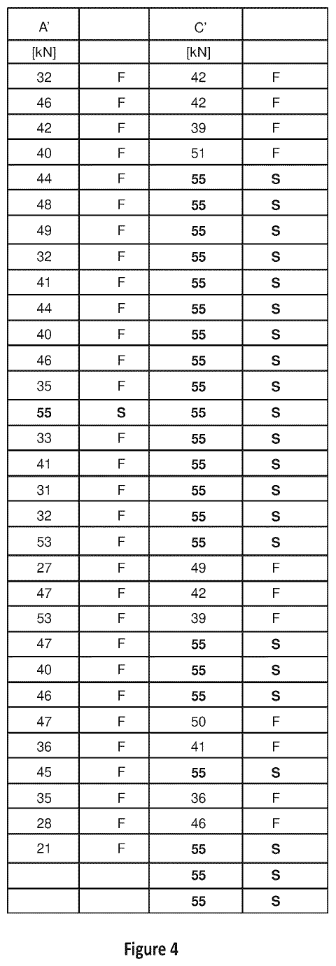

FIG. 4 is a comparison table comparing force at break or force at which testing was stopped for two other batches of sapphire crystals of types A and C respectively, subjected to an annular bending test.

One embodiment of a wristwatch 200 comprising a watch case 100 of axis A100 is described with reference to FIG. 1. The wristwatch further comprises a watch movement, mounted in the wristwatch case 100, which protects it from the external environment.

The watch case 100 chiefly comprises a case middle 3, a load-reacting ring 2, and a crystal 1. It also comprises a sealing device.

The watch case 100 according to the embodiment additionally comprises an annular seal 5 interposed notably between the case middle 3 and the load-reacting ring 2. It also comprises a clamping ring 6 which is intended to clamp said annular seal 5. The annular seal 5 notably allows the crystal 1 to remain in contact with the load-reacting ring 2. Such a design offers the advantage of dissociating the ability to withstand pressure from the watertight sealing since the compression of the crystal 1 does not crush the seal 5 between the crystal 1 and the load-reacting ring 2. The back 4 moreover bears against the load-reacting ring 2, on the opposite side from the crystal 1. According to the case embodiment illustrated in FIG. 1, the back 4 is of one piece and is screwed onto the case middle 3. A seal 9 is placed in a groove 4a in the back 4, in order to constitute a watertight interface between the case middle 3 and the back 4.

The crystal 1, the load-reacting ring 2, and the back 4 thus define a protective casing 10. In particular, this casing has a compression-resistant cross section SR in a plane passing through the axis A100, this cross section comprising a surface 1a of the crystal 1 bearing against a load-reacting surface 2a of the load-reacting ring 2, as well as a back surface 4b bearing against a surface 2b of the load-reacting ring 2, these surfaces being superposed with one another in a direction parallel to the axis A100, this superposition being without discontinuity. Advantageously, the surface 1a is in direct contact with the load-reacting surface 2a. In other words, as a preference, no seal is compressed at the interface between the surfaces 1a and 2a.

As a preference, the surfaces 1a and 2a are plane. As a preference, the surfaces 1a and 2a extend perpendicular or substantially perpendicular to the axis A100. Alternatively, the surfaces 1a and 2a could be oblique. As a further alternative, the surfaces 1a and 2a could be curved. Likewise, as a preference, the surfaces 2b and 4b are plane. As a preference, the surfaces 2b and 4b extend perpendicular or substantially perpendicular to the axis A100. Alternatively, the surfaces 2b and 4b could be oblique. As a further alternative, the surfaces 2b and 4b could be curved.

A bezel 7 is also attached to the clamping ring 6 by a connecting ring 8 fixed around said ring 6. This bezel 7 notably comprises a ring 7a collaborating with the connecting ring 8, as well as a disk 7b fixed to said ring 7a, notably by driving or clip-fastening. The bezel 7 may be mounted fixedly on the case middle 3. Alternatively, the bezel 7 may be a rotary bezel, which is to say mounted able to rotate on the case middle 3 about the axis A100.

According to the invention, the watch case 100 is provided with a crystal 1 that is particularly well suited to withstanding very high external pressures. For that, the crystal 1 is made of sapphire having an optical axis perpendicular or substantially perpendicular to the plane of the crystal 1.

In particular, according to the embodiment, the crystal 1 has a “type C” crystallographic orientation, indicated schematically in FIG. 2b, as compared with a traditional sapphire crystal, depicted in FIG. 2a, said to be of “type A”. FIGS. 2a and 2b therefore illustrate sapphire crystals respectively of types A and C, in which it has been indicated that the material is anisotropic. The result of this anisotropy is that the mechanical properties of the sapphire, such as the Young's modulus, the Poisson's ratio and/or the stress at break in particular, vary according to the direction of applied stress, and that the behavior of the two types of sapphire with different orientations likewise varies.

In practice, a number of tests have been performed in order to illustrate the significant gains in mean stress at break achieved by a sapphire crystal used by the invention.

In particular, a first bending test, a Ball-on-3-Balls (also known by its abbreviation B3B) biaxial bending test, was carried out using type C crystals. This test is able to reproduce on a crystal a stress field substantially similar to that experienced by the crystal during watertightness tests. By way of example, FIG. 3 illustrates a graph providing a comparison between the mean breaking stresses, from a B3B test, of two batches of crystals of types A and C respectively. More specifically, batch A comprises 292 sapphire crystals with a “type A” crystallographic orientation, and batch C comprises 73 sapphire crystals with a “type C” crystallographic orientation.

It may be observed, notably from FIG. 3, that the mean breaking stress is of the order of 1700 MPa for the batch of traditional-orientation (type A) crystals and of the order of 3500 MPa for the batch of crystals with an orientation according to the invention (type C). Note that these results are independent of the thickness of the crystal because it is breaking stresses that are being considered here.

A second bending test, a ring bending test, that better reproduces the stresses caused by a hydrostatic pressure when the watch case is submerged, was carried out. More specifically, this second test consists in applying a force normal to the upper surface of the crystal, against the center of the crystal (using a ball for example) and directed toward the inside of the watch case, while the periphery of the crystal is bearing against a load-reacting surface of the load-reacting ring of a watch case, or of a fixture. By way of example, the aforementioned force advantageously passes along the axis A100 illustrated in FIG. 1, while the lower surface of the crystal is bearing against the load-reacting surface 2a of the load-reacting ring 2.

This second test made it possible to determine the levels of force at break for crystals of thickness e1=5.5 mm of types A and C respectively. More specifically, this second test was performed on the basis of a batch A′ comprising 31 sapphire crystals with “type A” orientation, and a batch C′ comprising 33 sapphire crystals having a “type C” orientation. FIG. 4 gives values for force at break (followed by an “F”) or force at which the test was stopped (followed by an “S”) in the case of the crystals which did not break, for which the force at break is higher than the force at which the test was stopped. This force at which the test was stopped is given by the limits of the equipment, notably those of the fixture, participating in the test. This force at which the test was stopped is equal to 55 kN here.

A statistically significant difference in levels of breakage may be observed between the two batches A′ and C′ tested. Batch A′ exhibits 97% of breakages (30 crystals broken at the end of the test, out of 31 crystals tested), whereas batch C′ exhibits 33% breakages (11 crystals broken at the end of the test, out of 33 crystals tested).

A statistical analysis of the distributions of the force at break for the two batches A′ and C′ using, for example, a normal distribution curve results in significant deviation in both mean and spread. In particular, accounting for censoring, the mean of the forces at break for the crystals of batch C′ is approximately 50% higher than that for batch A′, of the order of 60 kN as against 40 kN.

It then follows from these tests that, for a sapphire crystal of a given thickness e1, the mean stress at break and the mean force at break are higher for a crystal having a “type C” orientation than for a crystal having a “type A” orientation. It is thus possible to minimize the thickness of a sapphire crystal while maintaining predefined mechanical performance by selecting a sapphire crystal that specifically has a “type C” orientation as a replacement for a thicker crystal of “type A” orientation.

In particular, the act of choosing a crystal of “type C” orientation makes it possible to minimize the thickness e1 of a crystal 1, particularly to a value less than or equal to 11 mm, for a dive wristwatch 200 able to remain watertight down to a depth of 11,000 meters. Indeed, simulations show that a crystal having a thickness e1 equal to 9.5 mm, a total diameter of 37 mm, and having a bearing surface characterized by a ratio A2a/A1a=0.45, which will be detailed hereinafter, is able to withstand a pressure of 137.5 MPa. A sapphire crystal of “type C” orientation configured in this way is thus able to be fitted to a dive watch the protective casing of which is able to withstand pressure loadings in excess of 50 MPa, or even greater than 130 MPa, and may range as high as 137.5 MPa. In general, a crystal according to the invention may have a thickness of between 9.5 mm and 14 mm inclusive, or even between 9.5 mm and 11 mm inclusive, in order to withstand the aforementioned high pressures.

In order to validate these simulations, additional tests were successfully conducted on sapphire crystals according to the invention, having a thickness e1 of 9.5 mm and a “type C” orientation, assembled on imaginary cases and subjected to a maximum pressure of 145 MPa in a hyperbaric chamber. Impact tests, for example drop tests and tests of the impact-ram type, were also carried out in order to validate the geometry of the crystal, and notably avoid any risk of chipping during wearing.

Finally, it would appear that the choice of sapphire crystal according to the invention surprisingly makes it possible to offer a mechanical strength that is higher by a factor of 2 compared with a crystal of “type A” orientation in which the optical axis is in the plane of the crystal.

The sapphire crystal 1 according to the embodiment may be obtained by a crystal growth method known as the “Kyropoulos technique” or by an EFG (edge-defined film-fed growth) method. More generally, the invention relates to the use of a sapphire crystal of which the optical axis is perpendicular or substantially perpendicular to the plane of the crystal 1, which is to say parallel to the axis of the watch case.

As has been detailed hereinabove, the invention relies first of all on the choice of a particularly advantageous sapphire crystal. To complement this, one advantageous embodiment consists in choosing for a load-reacting surface 2a of the watch case, on which surface the surface 1a of the crystal 1 bears, to be relatively large. Thus, according to the embodiment, the ratio A2a/A1a is greater than or equal to 0.2, or is even greater than or equal to 0.3, or is even greater than or equal to 0.35, or is even greater than or equal to 0.4, where A2a is the area of the load-reacting surface 2a of the load-reacting ring 2, against which surface at least a portion of the surface 1a of the crystal 1 bears, and A1a is the area of the surface 1a of the crystal 1. By way of example, the ratio A2a/A1a is of the order of 0.45 in the wristwatch case embodiment illustrated in FIG. 1. This area A1a of the crystal is preferably measured at its interior surface, which is to say at its surface position toward the inside of the watch case, facing toward the movement. As a preference, this surface 1a is perpendicular or substantially perpendicular to the axis A100 of the watch case 100. As a preference, this surface is continuous. Alternatively, this surface may comprise an oblique portion at least partially forming the contour of the crystal toward the inside of the watch case, to complement a portion perpendicular or substantially perpendicular to the axis A100 of the watch case 100. This surface 1a may be continuous or discontinuous. This surface 1a may be plane or curved or comprise plane or curved portions. This surface 1a will thus more generally be referred to as the interior surface 1a. It notably comprises the entire surface of the crystal, perpendicular to the axis A100 of the watch case 100 or oblique, bearing against another component of the watch case, particularly against the load-reacting ring 2. Advantageously, the entirety of the surface 2a of the load-reacting ring 2 bears against the crystal 1, particularly bearing against at least a portion of the surface 1a of the crystal 1. As a preference, this surface 2a is perpendicular or substantially perpendicular to the axis A100 of the watch case 100. Alternatively, this surface may be oblique. This surface 2a may be continuous or discontinuous. This surface 2a may be plane or curved or comprise plane or curved portions.

Furthermore, the invention allows the use of a crystal the thickness of which is reduced in comparison with the state-of-the-art. Naturally, this thickness is dependent on a number of parameters, such as its diameter and the load-reacting area, as well as the performance expected in terms of the watertightness of the watch case. However, it would appear that a thickness of 4 mm is already suitable for underwater diving to great depths, and that a thickness of up to 10 or 11 mm is sufficient to withstand the greatest depths, down to depths of 11,000 meters.

The case middle 3, the back 4 and the bezel ring 7a are notably made from a titanium alloy, particularly a grade 5 or grade 5 ELI (grade 23) titanium alloy. The density of such material advantageously makes it possible to minimize the mass of the case 100 as far as possible for a given case diameter and thickness.

According to the embodiment, the load-reacting ring 2 is made of nitrogen-doped stainless steel, for example a steel known by its reference P558. More generally, a steel with superior mechanical properties is chosen, particularly one having a high Young's modulus, notably greater than or equal to 150,000 MPa, and for example of the order of 200,000 MPa. This property allows it not to deform under the effect of the extreme pressures notably encountered at depths of 11,000 meters.

Furthermore, the offset (tensile) yield strength Rp0.2 of such a steel is of the order of 570 MPa. In order to prevent any risk of the load-reacting ring 2 entering the plastic domain, which ring may for example have a thickness e2 of 6.4 mm and a total diameter of 39.7 mm, particularly at its exterior periphery, the choice was made according to the embodiment to raise the offset (tensile) yield strength Rp0.2 of this steel to a value in excess of 620 MPa, notably of the order of 650 MPa. Such an approach should allow it to withstand extreme pressures, for example of at least 100 MPa. According to the embodiment, the yield strength of the material of which the load-reacting ring 2 is made is increased by work hardening, by creating blanks of the load-reacting ring 2 which are then deformed by striking. Tests have shown that a degree of work hardening of the material of the order of 10% makes it possible to arrive at such a yield strength of the order of 650 MPa. Such a level of work hardening moreover offers the second advantage of allowing the load-reacting ring 2 to be easily machinable while at the same time allowing termination levels in accordance with high-end horology standards. Thus, according to the embodiment of the invention, the material of which the load-reacting ring 2 is made has an offset yield strength Rp0.2 greater than or equal to 620 MPa, or even greater than or equal to 640 MPa, or even greater than or equal to 650 MPa, so that the protective casing offers the required specifications.

Alternatively, the load-reacting ring 2 may be made of ceramic, notably of zirconia.

To complement this, according to one embodiment, the back 4 is made of titanium alloy, notably an α+β or β titanium alloy, particularly a grade 5 or grade 5 ELI (grade 23) titanium alloy, as mentioned hereinabove. Such material advantageously makes it possible to minimize the mass of the watch case 100 while at the same time guaranteeing excellent mechanical properties. Advantageously, the titanium alloy is additionally thermally hardened in order to withstand extreme pressures, for example of 100 MPa, so as to avoid any risk of the back 4 entering the plastic domain. Tests have demonstrated that a heat treatment performed at a temperature below the beta transus temperature, ideally in a protective atmosphere, makes it possible to obtain an offset yield strength value Rp0.2 greater than 1000 MPa, of the order of 1100 MPa, namely an approximately 25% increase as compared with the offset yield strength Rp0.2 of annealed grade 5 titanium, which is usually comprised between 820 and 860 MPa.

More generally, such a heat treatment is particularly advantageous in allowing hardening of an α+β titanium alloy or of a β titanium alloy, particularly in achieving an offset yield strength value Rp0.2 greater than or equal to 1000 MPa, of the order of 1100 MPa. For the particular example of the hardening of a grade 5 titanium or a grade 5 ELI (grade 23) titanium alloy, an aging heat treatment performed by maintaining it at 520° C. for 4 h makes it possible, through the decomposition of the metastable phases, to increase the mechanical properties of the alloy sufficiently. The elastic-limit values thus obtained make it possible to avoid any risk of the back 4 entering the plastic domain for the dimensions corresponding to a wristwatch, for example for a back of a thickness e4 of 4.8 mm. Thus, more generally, the material of which the back 4 is made has an offset yield strength Rp0.2 greater than or equal to 1000 MPa, or even greater than or equal to 1100 MPa, so that the protective casing offers the required specifications.

Alternatively, the back 4 may be made of ceramic, notably of zirconia.

To complement this, as described hereinabove, the wristwatch case 100 additionally comprises a sealing device, formed by at least one seal, particularly an annular seal 5, interposed between the case middle 3 and the load-reacting ring 2 and between the clamping ring 6 and the crystal 1, thereby allowing the crystal 1 to be assembled on the case middle 3, particularly so that it bears against the ring 2. This annular seal 5 thus extends against the lateral flank of the crystal 1, and does not in any way extend against the interior surface of the crystal which bears exclusively against the load-reacting surface formed by the load-reacting ring 2. According to the cross section depicted in FIG. 1, the annular seal therefore extends in a direction parallel to the axis A100 of the watch case 100. According to the embodiment, the sealing device may comprise a second seal 9 forming a watertight interface between the case middle 3 and the back 4.

Naturally, the invention is not restricted to the geometry of the watch case 100 that has been depicted in FIG. 1. In particular, the load-reacting surface 2a could be oriented so that it is inclined with respect to the axis A100 of the watch case 100. In that case, the surface of the crystal 1 that is in contact with the load-reacting surface 2a would not be the interior surface of the crystal 1, which is to say a surface perpendicular to the axis A100, but rather would be a surface formed by a flank having an inclination corresponding to that of the load-reacting surface 2a. In other words, in such a configuration, the flank of the crystal would not be parallel to the axis A100 of the watch case, but inclined. It could thus for example have a frustoconical shape. Advantageously, in this embodiment, the angle between the inclined load-reacting surface 2a and the axis A100 of the case 100 is strictly less than 90 degrees.

As a further variant, this same cross section could comprise several portions with different shapes and/or inclinations, for example cross sections with different inclinations relative to the axis A100 of the watch case 100.

Naturally, in all cases, the peripheral portion of the crystal will substantially conform to the same shape as that of the load-reacting surface.

According to an embodiment variant, when the load-reacting surface 2a is inclined, a seal may be positioned between this load-reacting surface 2a and the crystal 1. In order to implement such a solution, it will be necessary to evaluate the load experienced by the seal and verify that this load is acceptable. In such a case, the crystal 1 bears indirectly against the load-reacting surface 2a, via a seal, whereas in the embodiment described with reference to FIG. 1 it was bearing directly against it.

Furthermore, in the embodiment described, a load-reacting ring 2 comprising the load-reacting surface 2a is distinct from the case middle 3.

As a variant, the load-reacting ring 2 and the case middle 3 may form just one single same component. In this last instance, the load-reacting surface 2a therefore belongs to the case middle 3. In that case, the case middle 3 (and the load-reacting ring 2 that it forms as a monolithic entity therewith) may comprise a flange on which the load-reacting surface 2a is arranged.

The load-reacting ring 2 may therefore be distinct from the case middle 3 and housed within the case middle, or formed as one with the case middle.

In addition, in all the embodiments described, the back 4 and the load-reacting ring 2 may be two distinct components or, as a variant, one and the same single component.

In the embodiment described, the watch case 100 has a cross section, perpendicular to its axis A100, of circular contour. As a variant, any other shape is possible such as, for example, a square shape or a rectangular shape.

Finally, it has been demonstrated that it is first of all possible to greatly strengthen a watch case simply through the use of a particular sapphire crystal, the crystallographic orientation of which is chosen specifically. Advantageously, the bearing surface of the crystal is chosen to have a surface area that is large enough to withstand high loadings.

In addition, it has also been demonstrated that, advantageously, it is sufficient to select a load-reacting ring 2 made from a hardened particular material the mechanical properties of which have been enhanced, and likewise optionally a back 4 made of a hard and particular material the mechanical properties of which have been enhanced, to enable the creation of a wristwatch case that is extremely strong, suitable for the greatest depths, with dimensions compatible with those desired for a wristwatch.

Notably, by virtue of the invention, it is possible to define a wristwatch of total thickness less than or equal to 28 mm, or even less than or equal to 26 mm, or even less than or equal to 24 mm, able to withstand pressure loadings in excess of 50 MPa or even in excess of 130 MPa, and potentially ranging as high as 137.5 MPa, namely a depth which may be as great as 11,000 meters. As a preference, the watch case will have a total thickness greater than or equal to 18 mm, or even greater than or equal to 22 mm.

The invention also relates to a wristwatch which comprises a watch case as defined hereinabove. Naturally, such a wristwatch will be particularly well suited to use in diving to very great depths.

1. A wristwatch case comprising:
a sapphire crystal having an optical axis perpendicular or substantially perpendicular to a plane of the crystal, and
a load-reacting surface,
wherein an interior surface of the crystal bears against the load-reacting surface, and
wherein a ratio A2a/A1a is greater than or equal to 0.2,
where
A2a is the area of the load-reacting surface, and
A1a is the area of the interior surface of the crystal.

2. The wristwatch case as claimed in claim 1, wherein the sapphire crystal has been obtained by Kyropoulos technique or by EFG method of crystal growth.

3. The wristwatch case as claimed in claim 1, wherein the load-reacting surface is oriented perpendicular to a main axis of the watch case, or wherein the load-reacting surface is at least partially inclined with respect to the main axis of the watch case.

4. The wristwatch case as claimed in claim 1, wherein the wristwatch case comprises a case middle, and wherein the load-reacting surface is a surface of a load-reacting ring distinct from the case middle.

5. The wristwatch case as claimed in claim 1, wherein the wristwatch case comprises a case middle forming a flange, corresponding to a load-reacting ring formed as one piece with the case middle, the load-reacting ring comprising the load-reacting surface.

6. The wristwatch case as claimed in claim 4, wherein the wristwatch case comprises a protective casing comprising the crystal, the case middle and the load-reacting ring housed within the case middle comprising the load-reacting surface against which the crystal bears, and a back bearing against the load-reacting ring.

7. The wristwatch case as claimed in claim 4, wherein the load-reacting ring is made from a material having an offset yield strength Rp0.2 greater than or equal to 620 MPa.

8. The wristwatch case as claimed in claim 4, wherein the load-reacting ring is made of a material or materials selected from the group consisting of nitrogen-doped stainless steel, hardened steel, and ceramic.

9. The wristwatch case as claimed in claim 4, wherein the wristwatch case comprises an annular seal and a clamping ring clamping the annular seal, the annular seal being interposed between the case middle and the load-reacting ring, and between the clamping ring and the crystal.

10. The wristwatch case as claimed in claim 1, wherein the wristwatch case comprises a back, and wherein the back is made from a material having an offset yield strength Rp0.2 greater than or equal to 1000 MPa.

11. The wristwatch case as claimed in claim 10, wherein the back is made of a material or materials selected from the group consisting of titanium alloy and ceramic.

12. The wristwatch case as claimed in claim 11, wherein the back is attached to the case middle notably by screwing, and wherein the back comprises a seal forming a watertight interface between the case middle and the back.

13. The wristwatch case as claimed in claim 1, wherein
the wristwatch case has a total thickness less than or equal to 28 mm and/or a total thickness greater than or equal to 18 mm,
the wristwatch comprises a crystal having a thickness in a range of from 9.5 to 14 mm, and
the wristwatch is able to withstand pressure loadings in excess of 50 MP.

14. A wristwatch comprising a watch case as claimed in claim 1.

15. The wristwatch case as claimed in claim 1, wherein the sapphire crystal has a “type C” crystallographic orientation.

16. The wristwatch case as claimed in claim 1, wherein the ratio A2a/A1a is greater than or equal to 0.4.

17. The wristwatch case as claimed in claim 7, wherein the offset yield strength Rp0.2 of the material from which the load-reacting ring is made is greater than or equal to 650 MPa.

18. The wristwatch case as claimed in claim 8, wherein material or materials of the load-reacting ring is or are selected from the group consisting of P558 steel, work-hardened steel, and zirconia.

19. The wristwatch case as claimed in claim 10, wherein the offset yield strength Rp0.2 of the material of the back wristwatch case is greater than or equal to 1100 MPa.

20. The wristwatch case as claimed in claim 11, wherein the material or materials of the back is or are selected from the group consisting of α+β or β titanium alloy, titanium alloy that has been hardened through heat treatment, and zirconia.
